(19) United States
(12) Patent Application Publication
(10) Pub. No.: US 2025/0300010 A1
(43) Pub. Date: Sep. 25, 2025

(54) METHOD FOR PATTERNING FOR CHEMICAL MECHANICAL POLISHING (CMP) ISO-DENSE BIAS COMPENSATION USING Z-HEIGHT

(71) Applicant: Tokyo Electron Limited, Tokyo (JP)

(72) Inventors: Jodi GRZESKOWIAK, Albany, NY (US); David POWER, Albany, NY (US); David CONKLIN, Saratoga Springs, NY (US)

(73) Assignee: Tokyo Electron Limited, Tokyo (JP)

(21) Appl. No.: 18/611,009

(22) Filed: Mar. 20, 2024

(51) Int. Cl. H01L 21/768; H01L 21/3105; H01L 21/321; H01L 21/67

(52) U.S. Cl. CPC H01L 21/7684; H01L 21/31053; H01L 21/3212; H01L 21/67219; H01L 21/76819; H01L 21/76877

(57) ABSTRACT

Aspects of the present disclosure provide a method for chemical mechanical polishing (CMP) iso-dense bias compensation using z-height. For example, the method can include forming a dielectric material on a substrate within a first region to form one or more first dielectric layers that are spaced from one another, and forming on a first one of the first dielectric layers a first height correction layer that has a first height that is determined based on a first pattern density of the first region. The method can also include depositing a conductive material on the substrate to fill one or more first trenches surrounded by the first dielectric layers and the first height correction layer and cover the first dielectric layers and the first height correction layer, and performing a planarization process to planarize the conductive material and the first height correction layer until uncovering the first dielectric layers.

### FIELD OF THE INVENTION

The present disclosure relates to chemical mechanical polishing (CMP) methods, and, more particularly, to methods for patterning for CMP iso-dense bias compensation using z-height.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Planarization is increasing important in semiconductor fabrication processes. In semiconductor devices where different pattern densities of device structures are formed on a semiconductor substrate, fabrication of the device structures with uniform structural profiles is challenging because of micro-loading effects of etching and planarizing processes.

### SUMMARY

Aspects of the present disclosure provide a method for chemical mechanical polishing (CMP) iso-dense bias compensation using z-height. For example, the method can include forming a dielectric material on a substrate within a first region to form one or more first dielectric layers that are spaced from one another. For example, the dielectric material can be formed on the substrate in a chemical vapor deposition process. As another example, the dielectric material can be formed on the substrate in a spin-on film deposition process. The method can also include forming a first height correction layer on a first one of the first dielectric layers. The first height correction layer can have a first height that is determined based on a first pattern density of the first region. The method can also include depositing a conductive material on the substrate to fill one or more first trenches surrounded by the first dielectric layers and the first height correction layer and cover the first dielectric layers and the first height correction layer. For example, the conductive material can include copper (Cu). As another example, the conductive material can include tungsten (W). As another example, the conductive material can include ruthenium (Ru). The method can also include performing a planarization process to planarize the conductive material and the first height correction layer until uncovering the first dielectric layers.

In an embodiment, the method can further include forming a second height correction layer on a second one of the first dielectric layers. The second one of the first dielectric layers can be closer than the first one of the first dielectric layers to a center of the first region and have a second height that is greater than the first height of the first one of the first dielectric layers.

In an embodiment, the method can further include forming the dielectric material on the substrate within a second region to form one or more second dielectric layers that are spaced from one another, depositing the conductive material on the substrate to fill one or more second trenches surrounded by the second dielectric layers and cover the second dielectric layers, and performing the planarization process to planarize the conductive material until uncovering the second dielectric layers, wherein the first pattern density can be greater than a second pattern density of the second region. In another embodiment, the method can further include forming a second height correction layer on one of the second dielectric layers. The second height correction layer can have a second height that is determined based on the second pattern density of the second region, and the second height can be less than the first height. In some embodiments, depositing the conductive material on the substrate to fill the second trenches surrounded by the second dielectric layers and cover the second dielectric layers can include depositing the conductive material on the substrate to fill the second trenches surrounded by the second dielectric layers and the second height correction layer and cover the second dielectric layers and the second height correction layer. In various embodiments, performing the planarization process to planarize the conductive material until uncovering the second dielectric layers can include performing the planarization process to planarize the conductive material and the second height correction layer until uncovering the second dielectric layers.

In an embodiment, the planarization process can be a chemical mechanical polishing (CMP) process.

Aspects of the present disclosure also disclose a wafer processing system. For example, the wafer processing system can include a film formation module that is configured to form a conductive material, a dielectric material and a first height correction layer. The wafer processing system can also include a planarization module that is configured to perform a planarization process to planarize the conductive material and the first height correction layer. The wafer processing system can also include a controller that is coupled to the film formation module and the planarization module, the controller configured to control the film formation module to form the dielectric material on a substrate within a first region to form one or more first dielectric layers that are spaced from one another, to form the first height correction layer on a first one of the first dielectric layers, the first height correction layer having a first height that is determined based on a first pattern density of the first region, and to form the conductive material on the substrate to fill one or more first trenches surrounded by the first dielectric layers and the first height correction layer and cover the first dielectric layers and the first height correction layer, and the planarization module to perform the planarization process to planarize the conductive material and the first height correction layer until uncovering the first dielectric layers. In an embodiment, the first height of the first height correction layer is varied and increases toward a center of the first region.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a plan view of an exemplary wafer processing system for fabricating a semiconductor device in accordance with some embodiments of the present disclosure;

FIGS. 2A-2C illustrate an intermediate step of a method of fabricating a semiconductor structure after a conductive material is deposited to fill spaces surrounded by a dielectric material and planarized to form first and second metal lines;

FIGS. 3A and 3B illustrate an intermediate step of an exemplary method of fabricating a semiconductor structure after a conductive material is deposited to fill spaces surrounded by a dielectric material and planarized to form first and second metal lines according to some embodiments of the present disclosure;

FIGS. 4A-4E illustrate a method of form a height correction layer according to some embodiments of the present disclosure;

FIG. 5 shows the thicknesses (uniformness) across a surface (e.g., measured in X axis) of three different dielectric layers prior to and after CMP;

FIGS. 6A and 6B show the topologies of a semiconductor structure that includes one or more dielectric layers coated with a height correction layer that is not corrected with respect to its height prior to and after CMP, respectively;

FIG. 6C shows the topology of a semiconductor structure that includes one or more dielectric layers coated with a height correction layer that is corrected with respect to its height based on the pattern density of a region within which the dielectric layers are located after CMP; and

FIG. 7 is a flow chart of an exemplary method for patterning for CMP iso-dense bias compensation using z-height according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

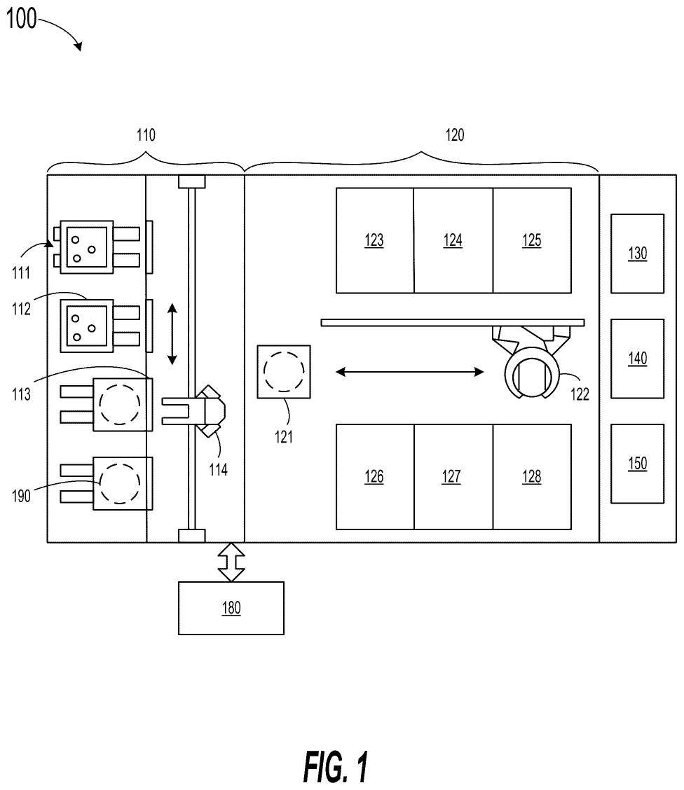

FIG. 1 is a plan view of an exemplary wafer processing system 100, e.g., a track lithography tool, for fabricating a semiconductor device in accordance with some embodiments of the present disclosure. The wafer processing system 100 can include various wafer handling components or carriers, along with several stages, e.g., a carrier stage 110 and a treatment stage 120. The carrier stage 110 can include one or more pod assemblies 111 that are configured to receive one or more wafer cassettes 112 that are configured to contain one or more wafers (or (singulated) dies) 190 that are to be processed in the wafer processing system 100. Doors 113 can open to access the wafers 190 contained in the wafer cassettes 112. A carrier transfer robot 114 can move up and down and transfer the wafers 190 from the wafer cassettes 112 to a shelf unit 121 that is installed in the treatment stage 120 for storing the wafers 190 temporarily.

The treatment stage 120 can include a variety of treatment modules, e.g., treatment modules 123-128, and a treatment transfer robot 122. The treatment transfer robot 122 can be configured to access the shelf unit 121 and the treatment modules 123-128 and transfer the wafers 190 among the treatment modules 123-128 for various processing. In an embodiment, the treatment transfer robot 122 can flip and rotate the wafers 190.

The treatment modules 123-128 can include one or more film formation modules 123 that are configured to deposit and form one or more films (or layers), e.g., a height (or thickness) correction film and a resist film, on a surface of the wafer 190 being processed. In an embodiment, the film formation module 123 can deposit and form the film, e.g., the high correction film and the resist film, on the frontside surface of the wafer 190 using chemical vapor deposition (CVD), atomic layer deposition (ALD), spin-on film deposition process, or other deposition techniques. For example, in the spin-on film deposition process an amount of a height correction material is deposited on the frontside surface of the wafer 190 while the wafer 190 is rotating, thus causing a solvent in the height correction material to evaporate and the properties of the deposited height correction material to change, to promote the adhesion of the height correction material to the frontside surface of the wafer 190. The height correction material can be any combination of films such as oxides, nitrides and/or spin-on films present on the frontside surface of the wafer 190.

The treatment modules 123-128 can also include one or more exposing modules 124, one or more baking modules 125, and one or more development modules 126. During a lithographic process, the film formation modules 123 can further form a resist film on the height correction film (or height correction material), the exposing modules 124 can be configured to expose the resist film with radiation or heat, the baking modules 125 can be configured to bake the wafer 190 to a target temperature, and the development modules 126 can be configured to develop a portion of the resist layer that has been exposed to the radiation, transfer the pattern of the remaining resist layer to the height correction film by etching the height correction film to form a final height correction film, and removing the remaining resist layer.

The wafer processing system 100 can further include a controller 180. The controller 180 can be a computer processor located within the wafer processing system 100, or located remotely but being in communication with components, e.g., the film formation module 123, the exposing modules 124, the baking modules 125 and the development modules 126. In an embodiment, the controller 180 can be configured to control the film formation module 123 to deposit a film, e.g., the height correction film and the resist film, on the frontside surface of the wafer 190, control the exposing modules 124 to expose the resist film with radiation or heat, control the baking modules 125 to bake the wafer 190 to a target temperature, and control the development modules 126 to develop a portion of the resist layer that has been exposed to the radiation, transfer the pattern of the remaining resist layer to the height correction film by etching the height correction film to form a final height correction film, and removing the remaining resist layer.

The wafer processing system 100 can also include other stages or components, e.g., a stepper/scanner 130, a singulation device 140 and a bonding tool 150. In an embodiment, the stepper/scanner 130 can be detached from the treatment stage 120 since the throughput of the stepper/scanner 130 is often many times greater than the throughput of the carrier stage 110 and the treatment stage 120, and thus dedicating the stepper/scanner 130 to a single treatment stage wastes the stepper/scanner's excess throughput capacity. The singulation device 140 can be configured to dice and singulate a wafer, e.g., the wafer 190, to obtain a plurality of chiplets. The bonding tool 150 can be configured to connect (join) an integrated chiplet (or die or wafer) with a wafer together in one mechanically stable package. The bonding tool 450 can employ direct wafer bonding (such as fusion bonding and anodic bonding) or wafer bonding with intermediate material (such as solder bonding and eutectic bonding) to bond a wafer/chiplet with a wafer/chiplet.

The treatment modules 123-128 can also include one or more planarizing modules 127 that are controlled by the controller 180 and configured to perform a planarization process, e.g., chemical mechanical polishing (CMP) process, to planarize the wafer 190. In CMP, a polishing slurry is introduced that facilitates the planarization and partial removal of one or more different materials (e.g., metal, dielectric and barrier materials in back-end-of-line (BEOL) and nitride and oxide in front-end-of-line (FEOL)) formed on the frontside surface of the wafer 190 through a combination of chemical reaction and physical abrasion. As the different materials may vary in hardness and pattern density, it is difficult to achieve a high degree of surface uniformity, particularly across a surface extending from a dense array of features, e.g., metal (e.g., copper, tungsten, ruthenium (Ru) or some other suitable metal) lines, bordered by an isolated field. The non-uniformed or uneven wafer topology caused by CMP is primarily due to erosion and dishing as a result of iso-dense bias.

Dishing is defined as a difference between the height of a feature (e.g., copper interconnect and silicon dioxide shallow trench isolation (STI)) in a trench and that of a dielectric layer in spaces surrounding the trench. Dishing can be positive if the feature in the trench is lower than the neighboring dielectric layer or can be negative if the feature sticks up above the neighboring dielectric layer. Erosion is defined as a difference between the thicknesses of the dielectric layer before and after CMP. Hence, erosion is the loss in the thickness of the dielectric layer during CMP and is always positive. The sum of dishing and erosion gives the feature thickness loss (also known as the copper thinning effect) during CMP. Dishing and erosion depend on layout patterns (e.g., interconnect width and space, and pattern density), polishing (e.g., CMP) process settings (e.g., down force, table speed, and slurry flow rate), over-polishing time, and so on. In addition, dishing and erosion on metal level one could lead to increased dishing and erosion and, therefore, more non-uniformed wafer surface on metal level two.

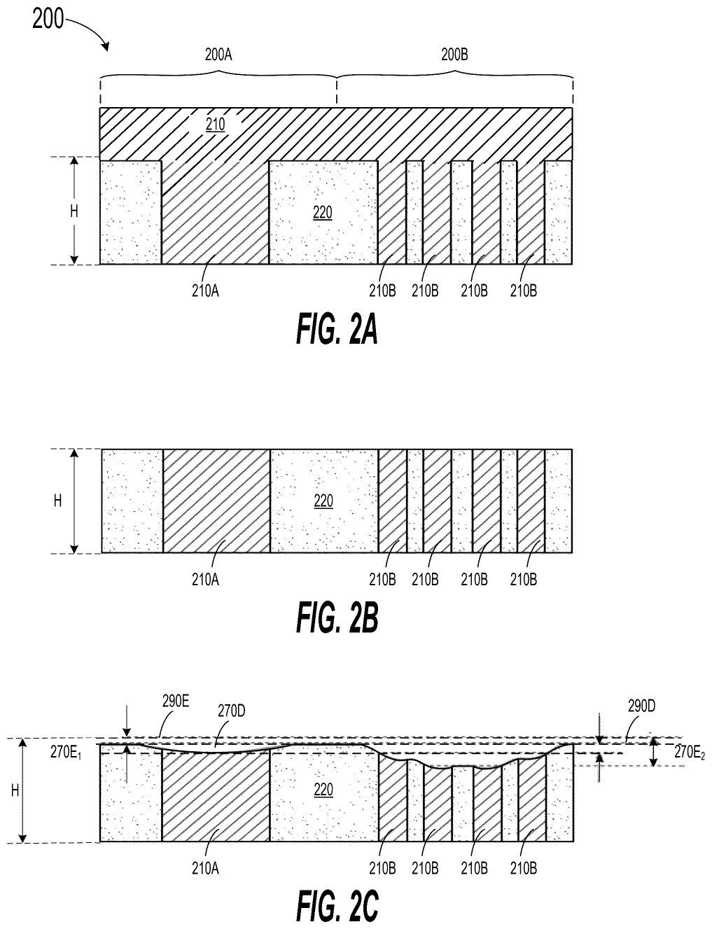

FIG. 2A illustrates an intermediate step of a method of fabricating a semiconductor structure 200 after a conductive material 210 (such as metal, e.g., copper (Cu), tungsten (W), ruthenium (Ru) or some other suitable metal) is deposited to fill spaces surrounded by a dielectric material 220 that is in height (or thickness) H and planarized to form first and second metal lines 210A and 210B. As shown in FIG. 2A, the semiconductor structure 200 can be divided into a first (isolated) region 200A and a second (dense) region 200B and, within which the second metal lines 210B have a denser pattern density than the first metal lines 210A formed within the isolated region 200A. Following the deposition of the conductive material 210, a planarization process, e.g., CMP process, can be performed to polish and planarize the surface of the semiconductor structure 200 down to the dielectric material 220 to remove the overburden portion of the conductive material 210. Ideally, after the CMP process the semiconductor structure 200 would have a uniform or even wafer topology and both the conductive material 210 (i.e., the first and second metal lines 210A and 210B) and the dielectric material 220 of the semiconductor structure 200 would be in height H, as shown in FIG. 2B. However, the conductive material 210 and the dielectric material 220 may be polished at different polishing rates during CMP process due to the difference in their hardness and pattern densities, and, as a result, the surface of the semiconductor structure 200 may be non-uniformed or uneven, which is caused by CMP due to erosion and dishing as a result of iso-dense bias.

The loading effect of CMP process will polish dense features, e.g., the second metal lines 210B within the dense region 200B, at different polishing rates than isolated features, e.g., the first metal lines 210A within the isolated region 200A. Therefore, the second metal lines 210B and a portion of the dielectric material 220 within the dense region 200B will be polished and removed more during CMP process than the first metal lines 210A and the remaining of the dielectric material 220 within the isolated region 200A, and, as a result, erosion occurs, creating a first erosion cavity 270E1 within the isolated region 200A and a second erosion cavity 270E2 within the dense region 200B compared to an ideal surface represented by a non-erosion line 290E, the second erosion cavity 270E2 being larger and deeper than the first erosion cavity 270E1, as shown in FIG. 2C. During CMP process, excessive copper may be polished and removed from the first metal lines 210A and the second metal lines 210B due to dishing. For example, excessive copper may be polished and removed from the first metal lines 210A, and, as a result, dishing occurs, creating a dishing cavity 270D compared to an ideal surface represented by a non-dishing line 290D and reducing the effective thickness of the first metal lines 210A.

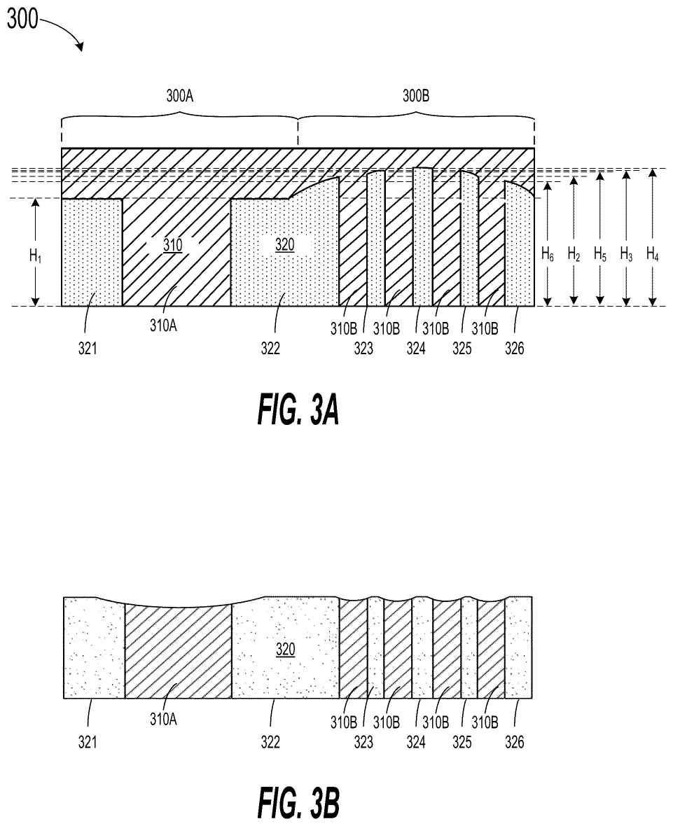

To address the above-mentioned issues, e.g., erosion, aspects of the present disclosure disclose methods for patterning for CMP iso-dense bias compensation using z-height. FIG. 3A illustrates an intermediate step of an exemplary method of fabricating a semiconductor structure 300 after a conductive material 310 (such as metal, e.g., copper (Cu), tungsten (W), ruthenium (Ru) or some other suitable metal) is deposited to fill spaces surrounded by a dielectric material 320 and planarized to form first and second metal lines 310A and 310B according to some embodiments of the present disclosure. The exemplary method can be implemented by a wafer processing system, e.g., the wafer processing system 100. As shown in FIG. 3A, the semiconductor structure 300 can also be divided into a first (isolated) region 300A and a second (dense) region 300B, within which the second metal lines 310B have a denser pattern density than the first metal lines 310A formed within the isolated region 300A.

The exemplary method illustrated in FIG. 3A differs from the method illustrated in FIG. 2A in that the dielectric material 320 (e.g., including first to sixth dielectric layers 321-326 formed) can vary in height (or thickness) in different regions based on their pattern densities (or iso-dense bias) in order to compensate the copper thinning effect caused by CMP due to dishing and erosion as a result of iso-dense bias. In an embodiment, first one or more of the first to sixth dielectric layers 321-326 within a first region that has a denser pattern density than a second region can be formed taller than second one or more of the first to sixth dielectric layers 321-326 within the second region. For example, the first dielectric layer 321 and any one of the second to sixth dielectric layers 322-326 are within the isolated region 300A and the dense region 300B, respectively, which has a dense pattern density than the isolated region 300A, and, therefore, any one of the second to sixth dielectric layers 322-326 (e.g., in heights (or thicknesses) H₂ to H₆, respectively) is formed taller than the first dielectric layer 321 (e.g., in height (or thickness) H₁) in order to compensate the more severe copper thinning effect caused by CMP within the dense region 300B due to dishing and erosion as a result of iso-dense bias.

In another embodiment, a first one of one or more of the first to sixth dielectric layers 321-326 that are within the same region (e.g., the isolated region 300A or the dense region 300B) can be formed taller than a second one if the first one is closer than the second one to a center of the region. For example, within the dense region 300B the fourth dielectric layer 324 is closer to the center of the dense region 300B than the third and fifth dielectric layers 323 and 325 than the second and sixth dielectric layers 322 and 326, and, therefore, is formed (e.g., in height H₄) taller than the third and fifth dielectric layers 323 and 325 (e.g., in heights H₃ and H₅, respectively) than the second and sixth dielectric layers 322 and 326 (e.g., in heights H₂ and H₆, respectively) in order to compensate the more severe copper thinning effect caused by CMP around the center of the dense region 300B due to dishing and erosion as a result of iso-dense bias.

In some embodiments, any one of the second to sixth dielectric layers 322-326, which are within the dense region 300B, can be formed to have a varied height (or an inclined top surface) that increases toward the center of the dense region 300B. For example, as shown in FIG. 3A the second and third dielectric layers 322 and 323 are formed taller at right side than at left side, while the fifth and sixth dielectric layers 325 and 326 are formed taller at left side than at right side.

Following the CMP iso-dense bias compensation using z-height on a portion of the dielectric material 320 that is within the dense region 300B (i.e., the second to sixth dielectric layers 322-326) in order to compensate the copper thinning effect caused by CMP due to dishing and erosion as a result of iso-dense bias, the conductive material 310 can be deposited to fill spaces surrounded by the dielectric material 320 (i.e., the first to sixth dielectric layers 321-326) and planarized to form the first and second metal lines 310A and 310B. As the dielectric material 320 (e.g., the second to sixth dielectric layers 322-326) and thus the second metal lines 310B within the dense region 300B are compensated with respect to their heights, i.e., offsetting their heights prior to CMP, and, therefore, the copper thinning effect (e.g., erosion) caused by CMP as a result of iso-dense bias can be mitigated, the semiconductor structure 300 may have a more uniform or evener wafer topology (or surface) within the dense region 300B, as shown in FIG. 3B, as compared with the semiconductor structure 200 within the dense region 200B shown in FIG. 2C.

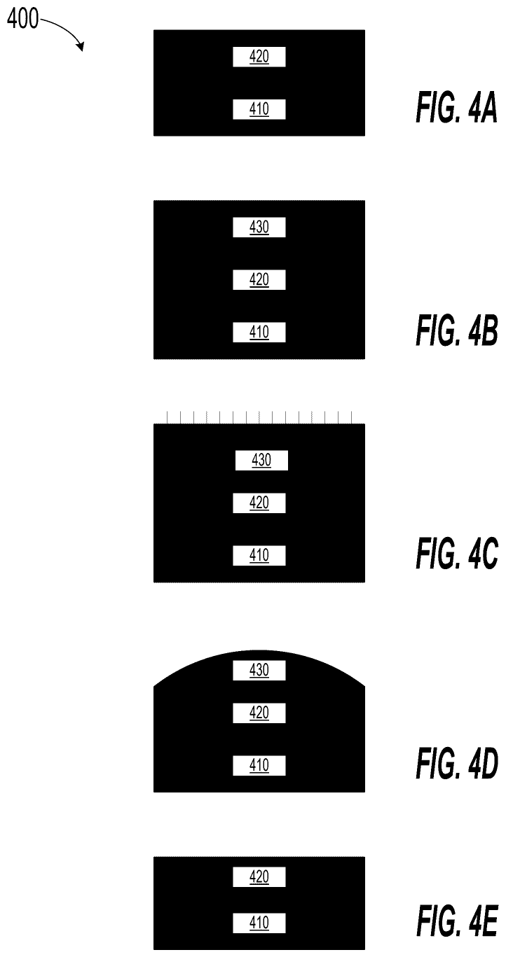

FIGS. 4A-4E illustrate intermediate steps of an exemplary method of fabricating a semiconductor structure 400 according to some embodiments of the present disclosure. In an embodiment, a dielectric layer, e.g., the second to sixth dielectric layers 322-326, may have its height compensated based on iso-dense bias. The exemplary method can be implemented by a wafer processing system, e.g., the wafer processing system 100. As shown in FIG. 4A, a substrate 410, e.g., Si or Ge substrate, can be provided, and a layer, e.g., a spin-on-glass (SOG) layer 420 (e.g., a lower portion of the dielectric material 320 below height H₁) can be formed (e.g., by the film formation modules 123) on the substrate 410. As shown in FIG. 4B, a height correction layer (or film) 430 (e.g., an upper portion of the dielectric material 320 above height H₁) can be formed (e.g., by the film formation modules 123) on the SOG layer 420. As shown in FIG. 4C, the height correction layer 430 can be exposed (e.g., by the exposing modules 124) with radiation or heat based on a pattern density of a region within which the height correction layer 430 (i.e., a dielectric layer located under the height correction layer 430, e.g., the lower portions of the second to sixth dielectric layers 322-326 below height H₁) is located. As shown in FIG. 4D, the exposed height correction layer 430 can be baked (e.g., by the baking modules 125) and developed (e.g., by the development modules 126) to form a final height correction film 430 (e.g., the upper portions of the second to sixth dielectric layers 322-326 above height H₁) that compensates and offsets the height of the dielectric layer (e.g., the lower portions of the second to sixth dielectric layers 322-326 below height H₁) located thereunder prior to CMP in order to mitigate the copper thinning effect (e.g., the erosion) caused by CMP as a result of iso-dense bias. As shown in FIG. 4E, the height correction layer 430 and the SOG layer 420 (that form a final dielectric layer, e.g., the second to sixth dielectric layers 322-326) can be polished by CMP to form a polished SOG layer 420. As the final dielectric material and thus one or more metal lines that fill trenches surrounded by the final dielectric layer are compensated with respect to their heights, i.e., offsetting their heights prior to CMP, and, therefore, the copper thinning effect (e.g., erosion) caused by CMP as a result of iso-dense bias can be mitigated, the semiconductor structure 400 thus may have a uniform or even wafer topology.

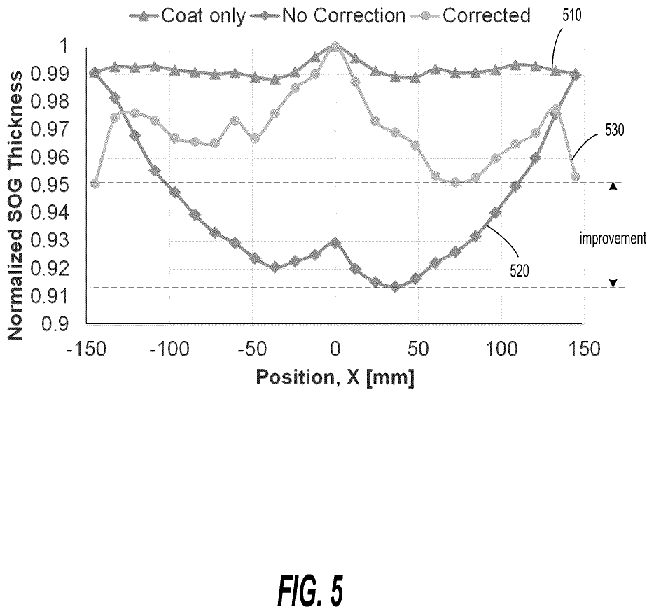

FIG. 5 shows the thicknesses (uniformness) across a surface (e.g., measured in X axis) of three different dielectric layers (e.g., the SOG layer 420 shown in FIG. 4E) prior to and after CMP. A first line 510 with triangular dots represents a dielectric layer (e.g., the SOG layer 420) coated with a height correction layer (e.g., the height correction layer 430) that is not corrected yet with respect to its height, as shown in FIG. 4B. A second line 520 with rectangular dots represents the dielectric layer coated with the height correction layer after CMP, which is not corrected yet with respect to its height prior to CMP. As shown, the dielectric layer represented by the second line 520 has smaller thicknesses around the origin (i.e., 0 mm) and larger thicknesses away from the origin (e.g., at +50, 100 and 150 mm), and the closer the dielectric layer is located to the origin the shorter the dielectric layer becomes, which corresponds to the dielectric material 220 shown in FIG. 2C. A third line 530 with round dots represents the dielectric layer coated with the height correction layer after CMP, which is corrected with respect to its height prior to CMP. As shown, the dielectric layer represented by the third line 530 has a very large portion (e.g., from −125 mm to 125 mm) that is taller than the dielectric layer represented by the second line 520 and has a larger total thickness mean and a smaller total thick variance (TTV) than the dielectric layer represented by the second line 520. Therefore, the dielectric layer represented by the third line 530 suffers less copper thinning effect and is more uniform or even than the dielectric layer represented by the second line 520. As shown in FIG. 5, a significant improvement of the thickness of the dielectric layer can be achieved if the height correction layer is formed and corrected with respect to its height based on the pattern density of a region within which the dielectric layer is formed.

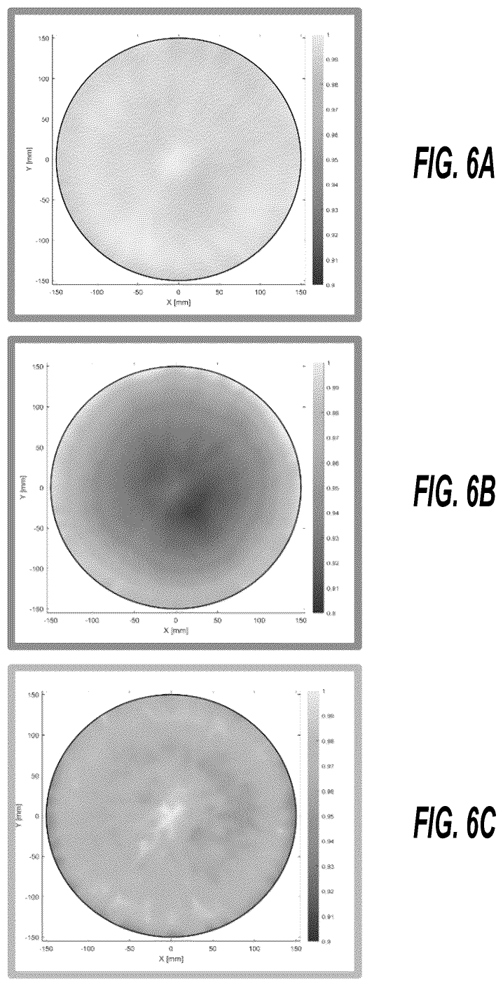

FIGS. 6A and 6B show the topologies (e.g., z-height variations) of a semiconductor structure that includes one or more dielectric layers (e.g., the dielectric layers represented by the first and second lines 510 and 520 shown in FIG. 5) coated with a height correction layer that is not corrected with respect to its height prior to and after CMP, respectively. FIG. 6C shows the topology (e.g., z-height variations) of a semiconductor structure that includes one or more dielectric layers (e.g., the dielectric layer represented by the third line 530 shown in FIG. 5) coated with a height correction layer that is corrected with respect to its height based on the pattern density of a region within which the dielectric layers are located after CMP. By comparing FIGS. 6B and 6C, it is found that the semiconductor structure that corresponds to FIG. 6C has more uniform or evener topology than the semiconductor structure that corresponds to FIG. 6B.

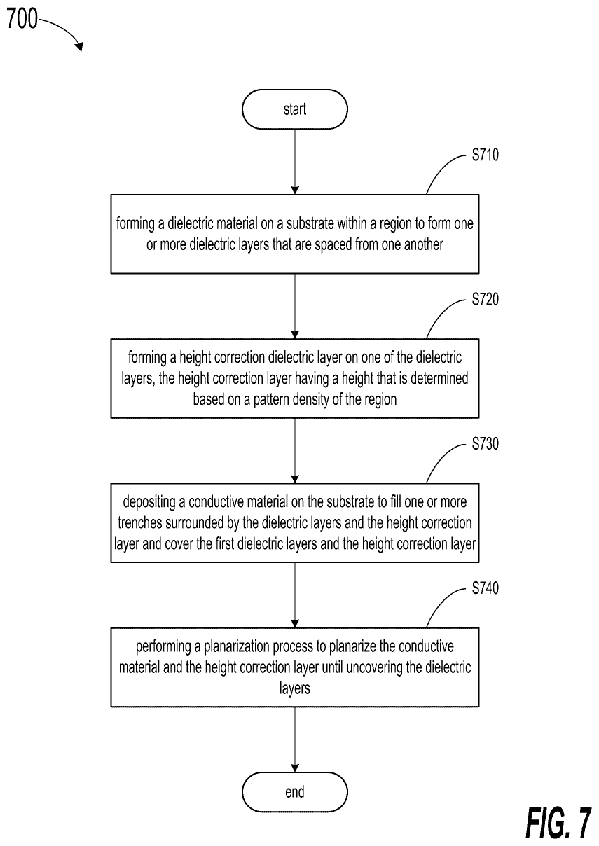

FIG. 7 is a flow chart of an exemplary method 700 for patterning for CMP iso-dense bias compensation using z-height to a semiconductor structure, e.g., the semiconductor structure 300 according to some embodiments of the present disclosure. In various embodiments, some of the steps of the method 700 shown can be performed concurrently or in a different order than shown, can be substituted by other method steps, or can be omitted. Additional method steps can also be performed as desired. Aspects of the method 700 can be implemented by a wafer processing system, e.g., the wafer processing system 100. The method 700 starts with step S710, at which a substrate can be provided, and a dielectric material can be formed on the substrate within a first region to form one or more first dielectric layers that are spaced from one another. For example, the dielectric material 320 can be formed, by the film formation module 123 in a chemical vapor deposition (CVP) process, on a substrate within the dense region 300B to form the second to sixth dielectric layers 322-326 (i.e., a lower portion of the second to sixth dielectric layers 322-326 below the height H₁), which are spaced from one another, as shown in FIG. 3A. The method 700 can proceed to step S720.

At step S720, a first height correction layer can be formed on a first one of the first dielectric layers, the first height correction layer having a first height that is determined based on a first pattern density of the first region. For example, the height correction layer 430 (i.e., an upper portion of the second to sixth dielectric layer 322-326 above the height H₁) can be formed, e.g., by the film formation module 123, on the lower portion of the third dielectric layer 323 below the height H₁, the height correction layer 430 having a first height that is determined based on a first pattern density of the dense region 300B, as shown in FIGS. 3A and 4D. In an embodiment, the first height of the first height correction layer can be varied and increase toward a center of the first region. For example, the height H of the lower and upper portions of the third dielectric layer 323 varies and increases toward the center of the dense region 300B, as shown in FIG. 3A. The method 700 can proceed to step S730.

At step S730, a conductive material can be deposited on the substrate to fill one or more first trenches surrounded by the first dielectric layers and the first height correction layer and cover the first dielectric layers and the first height correction layer. For example, the conductive material 310 can be deposited, e.g., by the film formation module 123, on the substrate to fill one or more first trenches surrounded by the lower and upper portions of the second to sixth dielectric layers and cover the lower and upper portions of the second to sixth dielectric layers 322-326, as shown in FIG. 3A. The method 700 can proceed to step S740.

At step S740, a planarization process can be performed to planarize the conductive material and the first height correction layer until uncovering the first dielectric layers. For example, the planarization process can be performed, e.g., by the planarizing modules 127, to planarize the conductive material 310 and the upper portion of the third dielectric layer 323 above the height H₁, as shown in FIG. 3B. In an embodiment, the conductive material and the first height correction layer can be polished when the planarization process is performed. For example, the planarization process can be a chemical mechanical polishing (CMP) process.

In an embodiment, the method 700 can further include a step of forming a second height correction layer on a second one of the first dielectric layers, the second one of the first dielectric layers being closer than the first one of the first dielectric layers to a center of the first region and having a second height that is greater than the first height of the first one of the first dielectric layers. For example, another height correction layer (i.e., an upper portion of the second to sixth dielectric layer 322-326 above the height H₁) can be formed, e.g., by the film formation module 123, on the lower portion of the fourth dielectric layer 324 below the height H₁, the fourth dielectric layer 324 being closer than the third dielectric layer 323 to a center of the dense region 300B and the another height correction layer being taller than the height correction layer 430.

In another embodiment, the method 700 can also include a step of forming the dielectric material on the substrate within a second region to form one or more second dielectric layers that are spaced from one another, depositing the conductive material on the substrate to fill one or more second trenches surrounded by the second dielectric layers and cover the second dielectric layers, and performing the planarization process to planarize the conductive material until uncovering the second dielectric layers, wherein the first pattern density is greater than a second pattern density of the second region. In some embodiments, the method 700 can also include a step of forming a second height correction layer on one of the second dielectric layers, the second height correction layer having a second height that is determined based on the second pattern density of the second region, the second height being less than the first height, wherein depositing the conductive material on the substrate to fill the second trenches surrounded by the second dielectric layers and cover the second dielectric layers includes depositing the conductive material on the substrate to fill the second trenches surrounded by the second dielectric layers and the second height correction layer and cover the second dielectric layers and the second height correction layer, and performing the planarization process to planarize the conductive material until uncovering the second dielectric layers includes performing the planarization process to planarize the conductive material and the second height correction layer until uncovering the second dielectric layers. For example, the dielectric material 320 can also be formed on the substrate within the isolated region 300A to form the first dielectric layer 321, the conductive material 310 can also be deposited on the substrate to fill the trench surrounded by the first dielectric layer 321, and the planarization process can be performed to planarize the conductive material 310 until uncovering the first dielectric layer 321, wherein the pattern density of the dense region is greater than the pattern density of the isolated region.

Aspects of the present disclosure also disclose a wafer processing system, e.g., the wafer processing system 100. For example, the wafer processing system can include a film formation module, e.g., the film formation module 123, that is configured to form a conductive material, a dielectric material and a first height correction layer. The wafer processing system can also include a planarization module, e.g., the planarization module 127, that is configured to perform a planarization process to planarize the conductive material and the first height correction layer. The wafer processing system can also include a controller, e.g., the controller 180, that is coupled to the film formation module and the planarization module, the controller configured to control the film formation module to form the dielectric material on a substrate within a first region to form one or more first dielectric layers that are spaced from one another, to form the first height correction layer on a first one of the first dielectric layers, the first height correction layer having a first height that is determined based on a first pattern density of the first region, and to form the conductive material on the substrate to fill one or more first trenches surrounded by the first dielectric layers and the first height correction layer and cover the first dielectric layers and the first height correction layer, and the planarization module to perform the planarization process to planarize the conductive material and the first height correction layer until uncovering the first dielectric layers. In an embodiment, the first height of the first height correction layer is varied and increases toward a center of the first region.

In an embodiment, the film formation module can be further configured to form a second height correction layer, and the controller can be further configured to control the film formation module to form the second height correction layer on a second one of the first dielectric layers, the second one of the first dielectric layers being closer than the first one of the first dielectric layers to a center of the first region and having a second height that is greater than the first height of the first one of the first dielectric layers.

In another embodiment, the controller can be further configured to control the film formation module to form the dielectric material on the substrate within a second region to form one or more second dielectric layers that are spaced from one another, and to form the conductive material on the substrate to fill one or more second trenches surrounded by the second dielectric layers and cover the second dielectric layers, and the planarization module to perform the planarization process to planarize the conductive material until uncovering the second dielectric layers, wherein the first pattern density is greater than a second pattern density of the second region. In another embodiment, the film formation module can be further configured to form a second height correction layer, and the controller can be further configured to control the film formation module to form the second height correction layer on one of the second dielectric layers, the second height correction layer having a second height that is determined based on the second pattern density of the second region, the second height being less than the first height, and to form the conductive material on the substrate to fill the second trenches surrounded by the second dielectric layers and the second height correction layer and cover the second dielectric layers and the second height correction layer, and the planarization module to perform the planarization process to planarize the conductive material and the second height correction layer until uncovering the second dielectric layers.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
forming a dielectric material on a substrate within a first region to form one or more first dielectric layers that are spaced from one another;
forming a first height correction layer on a first one of the first dielectric layers, the first height correction layer having a first height that is determined based on a first pattern density of the first region;
depositing a conductive material on the substrate to fill one or more first trenches surrounded by the first dielectric layers and the first height correction layer and cover the first dielectric layers and the first height correction layer; and
performing a planarization process to planarize the conductive material and the first height correction layer until uncovering the first dielectric layers.

2. The method of claim 1, further comprising:
forming a second height correction layer on a second one of the first dielectric layers, the second one of the first dielectric layers being closer than the first one of the first dielectric layers to a center of the first region and having a second height that is greater than the first height of the first one of the first dielectric layers.

3. The method of claim 1, further comprising:
forming the dielectric material on the substrate within a second region to form one or more second dielectric layers that are spaced from one another;
depositing the conductive material on the substrate to fill one or more second trenches surrounded by the second dielectric layers and cover the second dielectric layers; and
performing the planarization process to planarize the conductive material until uncovering the second dielectric layers,
wherein the first pattern density is greater than a second pattern density of the second region.

4. The method of claim 3, further comprising:
forming a second height correction layer on one of the second dielectric layers, the second height correction layer having a second height that is determined based on the second pattern density of the second region, the second height being less than the first height,
wherein depositing the conductive material on the substrate to fill the second trenches surrounded by the second dielectric layers and cover the second dielectric layers includes depositing the conductive material on the substrate to fill the second trenches surrounded by the second dielectric layers and the second height correction layer and cover the second dielectric layers and the second height correction layer, and
performing the planarization process to planarize the conductive material until uncovering the second dielectric layers includes performing the planarization process to planarize the conductive material and the second height correction layer until uncovering the second dielectric layers.

5. The method of claim 1, wherein the planarization process is a chemical mechanical polishing (CMP) process.

6. The method of claim 1, wherein the dielectric material is formed on the substrate in a chemical vapor deposition (CVD) process.

7. The method of claim 1, wherein the conductive material includes ruthenium (Ru).

8. The method of claim 1, wherein the conductive material includes copper (Cu).

9. The method of claim 1, wherein the conductive material includes tungsten (W).

10. The method of claim 1, wherein the dielectric material is formed on the substrate in a spin-on film deposition process.

11. A wafer processing system, comprising:
a film formation module configured to form a conductive material, a dielectric material and a first height correction layer;
a planarization module configured to perform a planarization process to planarize the conductive material and the first height correction layer; and
a controller coupled to the film formation module and the planarization module, the controller configured to control
the film formation module to form the dielectric material on a substrate within a first region to form one or more first dielectric layers that are spaced from one another, to form the first height correction layer on a first one of the first dielectric layers, the first height correction layer having a first height that is determined based on a first pattern density of the first region, and to form the conductive material on the substrate to fill one or more first trenches surrounded by the first dielectric layers and the first height correction layer and cover the first dielectric layers and the first height correction layer, and
the planarization module to perform the planarization process to planarize the conductive material and the first height correction layer until uncovering the first dielectric layers.

12. The wafer processing system of claim 11, wherein
the film formation module is further configured to form a second height correction layer, and
the controller is further configured to control the film formation module to form the second height correction layer on a second one of the first dielectric layers, the second one of the first dielectric layers being closer than the first one of the first dielectric layers to a center of the first region and having a second height that is greater than the first height of the first one of the first dielectric layers.

13. The wafer processing system of claim 11, wherein the controller is further configured to control
the film formation module to form the dielectric material on the substrate within a second region to form one or more second dielectric layers that are spaced from one another, and to form the conductive material on the substrate to fill one or more second trenches surrounded by the second dielectric layers and cover the second dielectric layers, and
the planarization module to perform the planarization process to planarize the conductive material until uncovering the second dielectric layers,
wherein the first pattern density is greater than a second pattern density of the second region.

14. The wafer processing system of claim 13, wherein
the film formation module is further configured to form a second height correction layer, and
the controller is further configured to control
the film formation module to form the second height correction layer on one of the second dielectric layers, the second height correction layer having a second height that is determined based on the second pattern density of the second region, the second height being less than the first height, and to form the conductive material on the substrate to fill the second trenches surrounded by the second dielectric layers and the second height correction layer and cover the second dielectric layers and the second height correction layer, and
the planarization module to perform the planarization process to planarize the conductive material and the second height correction layer until uncovering the second dielectric layers.

15. The wafer processing system of claim 11, wherein the planarization process is a chemical mechanical polishing (CMP) process.

16. The wafer processing system of claim 11, wherein the dielectric material is formed on the substrate in a chemical vapor deposition (CVD) process.

17. The wafer processing system of claim 11, wherein the conductive material includes ruthenium (Ru).

18. The wafer processing system of claim 11, wherein the conductive material includes copper (Cu).

19. The wafer processing system of claim 11, wherein the conductive material includes tungsten (W).

20. The wafer processing system of claim 11, wherein the film formation module is configured to form the dielectric material on the substrate in a spin-on film deposition process.
